(19) United States
(12) Patent Application Publication
(10) Pub. No.: US 2011/0281384 A1
(43) Pub. Date: Nov. 17, 2011

(54) METHOD OF MANUFACTURING THIN FILM TRANSISTOR AND METHOD OF MANUFACTURING FLAT PANEL DISPLAY USING THE SAME

(75) Inventors: Jun-Young Kim, Giheung-gu (KR); Chung Yi, Giheung-gu (KR); Shin-Jeong Han, Giheung-gu (KR); Gyung-Min Ko, Giheung-gu (KR)

(73) Assignee: SAMSUNG MOBILE DISPLAY CO. LTD., Yongin-si (KR)

(21) Appl. No.: 12/960,744

(22) Filed: Dec. 6, 2010

(30) Foreign Application Priority Data
May 13, 2010 (KR) 10-2010-0044904

(51) Int. Cl. H01L 33/42; H01L 21/84

(52) U.S. Cl. 438/34; 438/151; 257/E21.703; 257/E33.064

(57) ABSTRACT

A method of manufacturing a thin film transistor (TFT) and a method of manufacturing a flat panel display (FPD) using the same. A metal layer made out of Mo having no etch selectivity with a semiconductor layer so that a source electrode, a drain electrode, and an activation layer may be produced using a single mask in a single etch step. The metal layer and the semiconductor layer are simultaneously etched to form the source electrode, the drain electrode, and the activation layer, of a same width so that the area occupied by the TFT may be minimized. When the TFT is applied to the FPD, the maximal aperture ratio of pixels may be obtained and the FPD may be manufactured using only four masks.

### CLAIM OF PRIORITY

This application claims priority to and the benefit of Korean Patent Application No. 10-2010-0044904, filed on May 13, 2010, in the Korean Intellectual Property Office, the entire content of which is incorporated herein by reference.

### BACKGROUND OF THE INVENTION

1. Field of the Invention

The present invention relates to a method of manufacturing a thin film transistor (TFT) capable of minimizing an area occupied by the TFT and of maximizing the aperture of a pixel in a flat panel display (FPD) and a method of manufacturing a FPD using the same.

2. Description of the Related Art

A liquid crystal display (LCD) displays images and characters using the electro-optical characteristic of liquid crystal and has high color reproductivity, low power consumption and may be manufactured to be thin. The LCD is generally divided into passive matrix LCDs and active matrix LCDs. The active matrix LCDs having high resolution and high moving picture realizing ability are most commonly used.

The active matrix LCD includes a thin film transistor (TFT). The TFT as a switching element transmits an image signal provided by a data line to a pixel electrode in accordance with a scan signal provided by a gate line. The TFT includes a gate electrode coupled to the gate line, one of a source electrode and a drain electrode coupled to the data line, and an active semiconductor layer that provides a channel. Because more masks and processes are required to manufacture the active matrix LCD as compared to the passive matrix LCD, manufacturing costs increase and yield deteriorates due to the additional processes.

Furthermore, as resolution increases, the size of the TFT needs to be reduced. However, the amount the size of the TFT can be reduced is limited. Therefore, in the high resolution LCD, the aperture ratio of a pixel is unavoidably reduced so that brightness and picture quality deteriorate. What is therefore needed is an improved design for an active matrix LCD and an improved method of making that overcomes the above problems.

### SUMMARY OF THE INVENTION

Accordingly, the present invention has been made to provide a method of manufacturing a thin film transistor (TFT) capable of minimizing the number of masks used for manufacturing processes.

The present invention has also been made to provide a method of manufacturing the TFT capable of minimizing an area of the TFT.

The present invention has also been made to provide a method of manufacturing a flat panel display (FPD) capable of minimizing the number of masks used for manufacturing processes.

The present invention has also been made to provide a method of manufacturing a FPD capable of maximizing the aperture ratio of a pixel.

According to one aspect of the present invention, there is provided a method of manufacturing a thin film transistor (TFT), including forming a gate electrode on a substrate, forming a gate insulating layer on the substrate that includes the gate electrode, forming a semiconductor layer and a metal layer on the gate insulating layer, forming a photosensitive layer pattern on the metal layer that includes the gate electrode, the photosensitive layer pattern having a center portion having a first thickness and opposing edge portions having a second and larger thickness, wet etching an exposed portion of the metal layer and a portion of the metal layer under the opposing edge portions of the photosensitive layer pattern using the photosensitive layer pattern as an etch mask, removing a uniform thickness of the photosensitive layer pattern while etching an exposed portion of the semiconductor layer by a first etch on the photosensitive layer pattern, performing a second etch on the photosensitive layer pattern so that the edge portions of the photosensitive layer pattern coincide with side walls of the metal layer and dry etching the metal layer and an exposed portion of the semiconductor layer using the photosensitive layer pattern as a mask.

The substrate may be made out of one of a semiconductor and a transparent insulating material. The semiconductor layer may be made out of one of amorphous silicon and polysilicon. The metal layer may be made out of Mo. The photosensitive layer pattern may be produced using one of a half tone mask and a slit mask. The second etch of the photosensitive layer pattern may be a plasma etching process. The dry etching of the metal layer and the semiconductor layer may be a plasma etching process, an SF₆ gas and a chlorine gas are included as reaction gases.

According to another aspect of the present invention, there is provided a method of manufacturing a flat panel display (FPD), including forming a gate electrode on a substrate, forming a gate insulating layer on the substrate that includes the gate electrode, forming a semiconductor layer and a metal layer on the gate insulating layer, forming a photosensitive layer pattern on the metal layer that includes the gate electrode, the photosensitive layer pattern having a center portion having a first thickness and opposing edge portions having a second and larger thickness, wet etching an exposed portion of the metal layer and a portion of the metal layer arranged under the opposing edge portions of the photosensitive layer pattern using the photosensitive layer pattern as an etch mask, removing a uniform thickness of the photosensitive layer pattern while etching an exposed portion of the semiconductor layer by a first etch on the photosensitive layer pattern, performing a second etch on the photosensitive layer pattern so that the edge portions of the photosensitive layer pattern coincide with side walls of the metal layer, forming a source electrode and a drain electrode by etching the metal layer exposed by the photosensitive layer pattern and forming an activation layer by etching exposed portions of the semiconductor layer, forming a protective layer on the gate insulating layer that includes the source electrode and the drain electrode, exposing one of the source electrode and the drain electrode by forming a via hole through the protective layer and forming a pixel electrode on the protective layer that is electrically connected to the one of the source electrode and the drain electrode through the via hole.

The substrate may be made out of a transparent insulating material. The semiconductor layer may be one of amorphous silicon and polysilicon. The metal layer may be made out of Mo. The photosensitive layer pattern may be produced by using one of a half tone mask and a slit mask. The second etch of the photosensitive layer pattern may be a plasma etching process. The dry etching of the metal layer and the semiconductor layer may be a plasma etching process, and SF₆ gas and a chlorine gas may be included as reaction gases. The pixel electrode may be made out of a transparent conductive material.

### BRIEF DESCRIPTION OF THE DRAWINGS

The accompanying drawings, together with the specification, illustrate exemplary embodiments of the present invention, and, together with the description, serve to explain the principles of the present invention.

FIGS. 1A to 1H are sectional views illustrating a method of manufacturing a thin film transistor (TFT) according to an embodiment of the present invention;

FIG. 2 is a perspective view illustrating a flat panel display (FPD) to which the present invention is applied; and

FIGS. 3A to 3D are sectional views illustrating a method of manufacturing a FPD according to another embodiment of the present invention.

### DETAILED DESCRIPTION OF THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the element or be indirectly on the element with one or more intervening elements interposed therebetween. Also, when an element is referred to as being “connected to” another element, it can be directly connected to the element or be indirectly connected to the element with one or more intervening elements interposed therebetween. Like reference numerals refer to like elements.

Hereinafter, preferred embodiments of the present invention will be described in detail with reference to the accompanying drawings. The following embodiments are provided so that the present invention is fully understood by those skilled in the art. This invention may be embodied in many different forms and should not be construed as being limited to the embodiments set forth herein.

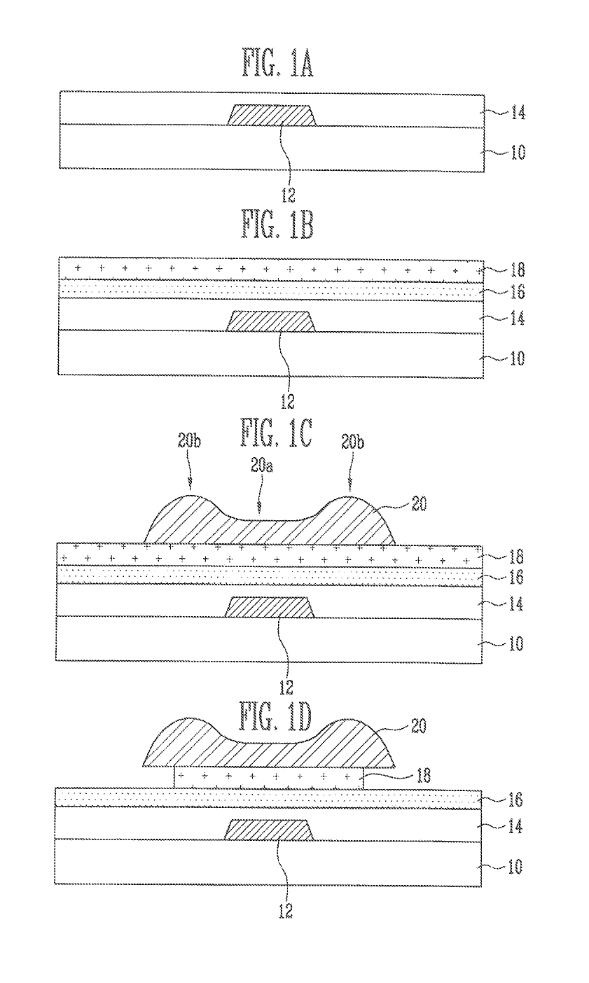

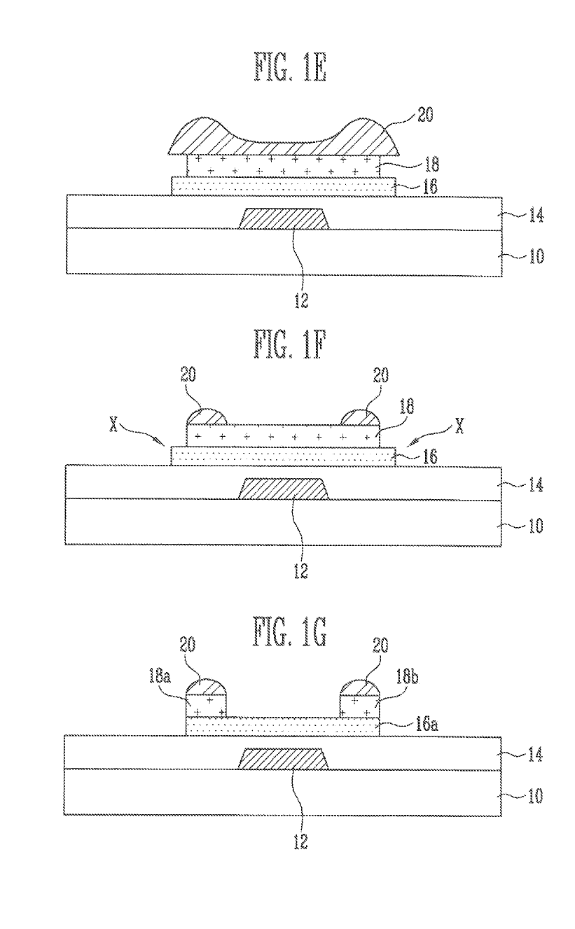

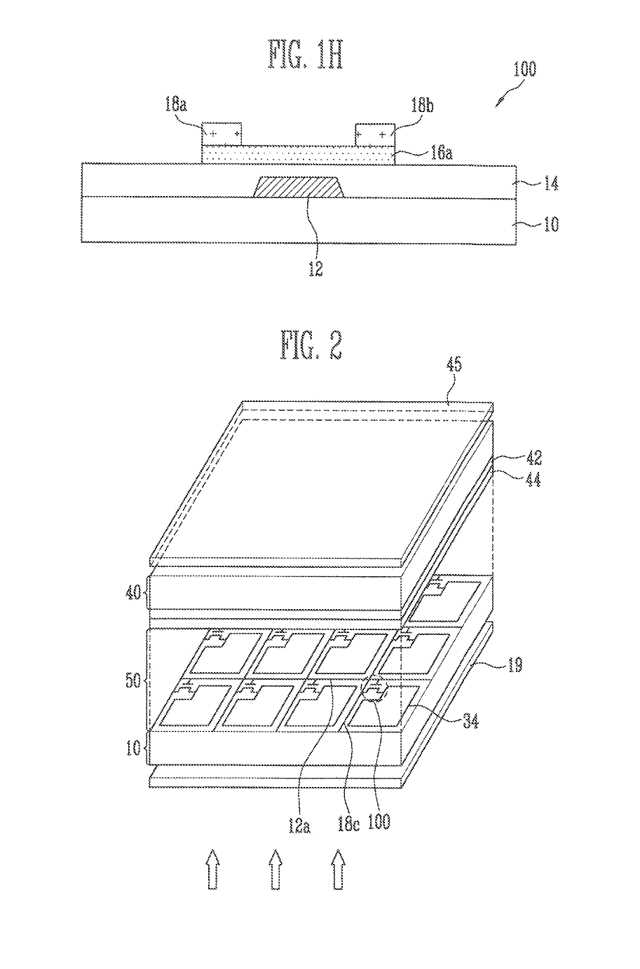

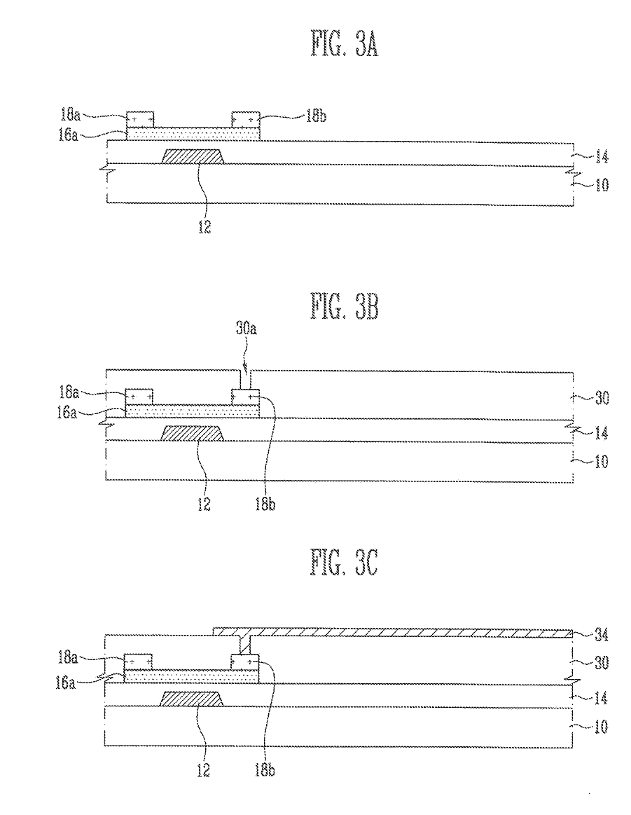

Turning now to FIGS. 1A to 1H, FIGS. 1A to 1H are sectional views illustrating a method of manufacturing a thin film transistor (TFT) according to an embodiment of the present invention. Referring to FIG. 1A, a gate electrode 12 is formed on a substrate 10 and a gate insulating layer 14 is formed on the substrate 10 that includes the gate electrode 12. Alternatively, a buffer layer (not shown) may further be formed on the substrate 10 prior to the formation of the gate electrode 12 and the gate insulating layer 14.

The substrate 10 is made out of an insulating material such as a semiconductor, transparent glass, or plastic. The gate electrode 12 is produced by depositing metal or doped polysilicon and by performing patterning by photolithography and etching processes using a first mask. Al, Mo, Cr, Ta, Ti, W, Cu, and Ag may be used as the metal for the gate electrode 12. The gate insulating layer 14 may be made out of a silicon oxide layer SiO₂, a silicon nitride layer SiN, or a lamination structure of the silicon oxide layer SiO₂ and the silicon nitride layer SiN.

Referring now to FIG. 1B, a semiconductor layer 16 and a metal layer 18 are sequentially formed on the gate insulating layer 14. The semiconductor layer 16, to be used as the active layer for a thin film transistor (TFT), is made out of amorphous silicon or polysilicon. The amorphous silicon is deposited and is crystallized by a laser. The metal layer 18, to be used as a source electrode and a drain electrode, is made out of Mo.

Referring now to FIG. 1C, a photosensitive layer pattern 20 having a center portion 20a of a first thickness and edge portions 20b of a second thickness and larger thickness is formed on the metal layer 18. After forming the photosensitive layer on the metal layer 18, when exposing and developing processes are performed using a half tone mask or a slit mask as a second mask to pattern the photosensitive layer, the photosensitive layer pattern 20 having the first thickness and the second thickness may be formed.

Referring now to FIG. 1D, the exposed part of the metal layer 18 and a part of the metal layer 18 covered by the edge portions 20b of the photosensitive layer pattern 20 are wet etched using the photosensitive layer pattern 20 as an etch mask. The etchant may be obtained by mixing at least one solution of phosphate, acetic acid, and nitro acid with deionized water. The etching process using the wet etchant is a continuous isotropic etch that removes the exposed portion of the metal layer 18 and portions of the metal layer 18 arranged underneath edge portions 20b of the photosensitive layer pattern 20. The metal layer 18 under both edge portions 20b of the photosensitive layer pattern 20 are etched so that undercut is generated.

Referring now to FIG. 1E, when the photosensitive layer pattern 20 is etched by a uniform thickness during a first photosensitive layer pattern etch, an exposed portion of the semiconductor layer 16 is etched simultaneously. When plasma etching using an SF₆ gas as a reaction gas is used for the first photosensitive layer pattern etch, the exposed semiconductor layer 16 may be etched by a predetermined thickness during the first etching of the photosensitive layer pattern 20. When the etching process is performed, both side portions 20b to of the photosensitive layer pattern 20 coincide with both side walls of the semiconductor layer 16 so that the width of the photosensitive layer pattern 20 is equal to the width of the semiconductor layer 16.

Referring now to FIG. 1F, the photosensitive layer pattern 20 is further etched during a second photosensitive layer pattern etch so that the side walls of the photosensitive layer pattern 20 coincide with the side walls of the metal layer 18. When the ashing process is performed using an oxygen (O₂) gas atmosphere, the thickness of the photosensitive layer pattern 20 is uniformly reduced. When the center part 20a of photosensitive layer pattern 20 is removed, the process is completed so that only the opposite edge portions 20b remain. After the second photosensitive layer pattern etch, the sides of the photosensitive layer pattern 20 coincide with the sides of the metal layer 18, while both sides of the semiconductor layer 16 protrude from the sidewalls of the metal layer 18 as indicated by the X's in FIG. 1F.

Referring now to FIG. 1G, exposed portions of the metal layer 18 and exposed portions of the semiconductor layer 16 are dry etched using the photosensitive layer pattern 20 as a mask. When plasma etching is performed using a reaction gas atmosphere that includes SF₆ and a chlorine gas, the exposed portions of the metal layer 18 are etched to form a source electrode 18a and a drain electrode 18b while the exposed portions X of the semiconductor layer 16 are simultaneously etched to complete an activation layer 16a. The gate electrode 12 is positioned to overlap the channel region of the activation layer 16a while the source electrode 18a and the drain electrode 18b are positioned to overlap the source region and the drain region of the activation layer 16a.

Referring now to FIG. 1H, the remaining photosensitive layer pattern 20 is removed, thereby completing the TFT 100.

According to the present invention, the metal layer 18 is made out of Mo (i.e., Molybdenum) so that there is very little or no etch selectivity with the semiconductor layer 16 so that the source electrode 18a, the drain electrode 18b, and the activation layer 16a may be formed using one mask (i.e., the second mask). No etch selectivity means that the Mo metal layer 18 and the semiconductor layer 16 have equal or nearly equal etch rates. In addition, the metal layer 18 and the semiconductor layer 16 are simultaneously etched during the removal of protruding parts X of semiconductor layer 16 so that the source electrode 18a, the drain electrode 18b, and the activation layer 16a may be formed to have the same width. Therefore, the number of masks used, the complexity of the manufacturing process and the area occupied by the TFT 100 may be minimized.

For example, when the metal layer 18 is made out of a metal such as Al having a high etch selectivity with respect to the semiconductor layer 16, the semiconductor layer 16 does not get etched when the aluminum metal layer 18 is being etched during the formation of the source electrode 18a and the drain electrode 18b. This is because the etch rate of the semiconductor layer 16 is much lower than the etch rate of the aluminum metal layer, resulting in a highly selective etch. Therefore, since the protruding portions X of the semiconductor layer 16 remain after an etch of the metal layer 18 when metal layer 18 is made out of aluminum, the area occupied by the TFT increases by the protruding portions X when as compared to the case when metal layer 18 is made out of Mo.

The above method of manufacturing the TFT according to the present invention may be applied to the method of manufacturing the FPD that includes the TFT. First, the FPD to which the present invention is applied will be described with reference to FIG. 2.

The FPD includes two substrates 10 and 40 arranged to face each other and a liquid crystal layer 50 interposed between the two substrates 10 and 40. On substrate 10, a pixel is defined by a plurality of gate lines 12a and data lines 18c arranged in a matrix. On the substrate 10 at the intersections of the gate lines 12a and the data lines 18c, the TFTs 100 for controlling signals applied to pixels and pixel electrodes 34 coupled to the TFTs 100 are formed. Capacitors (not shown) for maintaining the signals may be coupled to the TFTs 100.

A color filter 42 and a common electrode 44 are formed on substrate 40. On exterior surfaces of the substrates 10 and 40, polarizing plates 19 and 45 are arranged. Below the polarizing plate 19, a backlight is provided (not shown) as a light source. In addition, a driving unit (LCD drive IC) (not shown) for driving the pixels is mounted on the FPD. The driving unit converts electrical signals provided from the outside into scan signals and data signals and supplies the scan signals and the data signals to the gate lines 12a and the data lines 18c respectively.

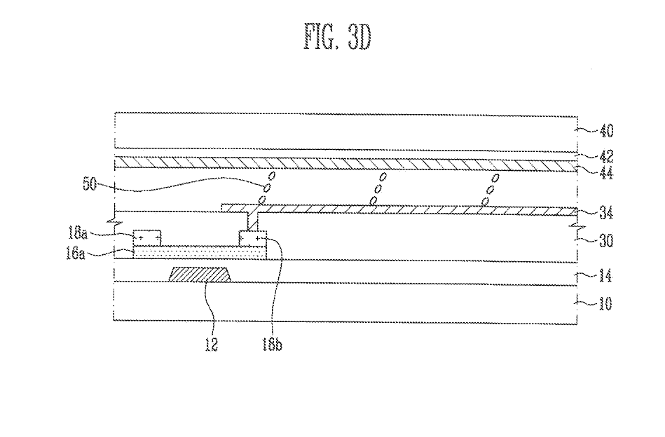

Turning now to FIGS. 3A to 3D, a method of manufacturing the FPD having the above structure will now be described. Referring to FIG. 3A, as illustrated in FIGS. 1A to 1H, the TFT 100 is manufactured on the substrate 10 made out of an insulating material such as transparent glass or plastic. As illustrated in FIG. 1A, when the gate electrode 12 is formed, the gate lines 12a are also formed. As illustrated in FIG. 1G, when the source electrode 18a and the drain electrode 18b are formed, the data lines 18c are also formed.

Referring to FIG. 3B, a protective layer 30 is formed on the gate insulating layer 14 including the source electrode 18a and the drain electrode 18b and a via hole 30a is formed in the protective layer 30 so that one of the source electrode 18a and the drain electrode 18b are exposed. The protective layer 30 may be formed by depositing inorganic materials such as a silicon oxide layer SiO₂ and/or a silicon nitride layer SiN or (and) organic materials such as acryl and/or polyimide. The protective layer 30 is patterned by photolithography and etching processes using a third mask to form a via hole 30a.

Referring to FIG. 3C, the pixel electrode 34 is formed on the protective layer 30 and is coupled to the exposed one of the source electrode 18a and the drain electrode 18b through the via hole 30a. After depositing a transparent conductive material such as indium tin oxide (ITO) or indium zinc oxide (IZO) on the protective layer 30 so that the via hole 30a is buried, patterning is performed by photolithography and etching processes using a fourth mask to form the pixel electrode 34.

Referring to FIG. 3D, the substrate 40 on which the common electrode 44 is formed to face the pixel electrode 34 is provided on the substrate 10 manufactured as described above. The space between the substrate 10 and the substrate 40 is sealed by a sealing material (not shown) so that the substrate 10 and the substrate 40 are separated from each other by a predetermined distance using a spacer (not shown). A liquid crystal 50 is injected into the sealed space between the substrate 10 and the substrate 40.

In the above-manufactured FPD, the light provided from a backlight (not shown) provided on the rear surface of the substrate 10 is incident on the liquid crystal layer 50 through the openings (transmitting parts) of the pixels, is modulated by the liquid crystal 50 oriented by the voltages applied to the pixel electrode 34 and the common electrode 44, and is emitted to the outside through the substrate 40 to display characters and/or images.

In the FPD, the size of the openings of the pixels that transmit light (i.e., the aperture ratio) significantly affects brightness and picture quality. According to the present invention, since the metal layer 18 and the semiconductor layer 16 are simultaneously etched to remove the protruding parts (the X parts of FIG. 1F) so that the source electrode 18a, the drain electrode 18b, and the activation layer 16a may have the same width, it is possible to prevent the aperture ratio from being reduced by the protruding parts (the X parts of FIG. 1F) of the semiconductor layer 16 so that the area occupied by the TFT 100 is minimized and maximal aperture ratio of the pixels may be obtained.

According to the present invention, since the metal layer 18 is made out of Mo having virtually no etch selectivity with semiconductor layer 16, the source electrode 18a, the drain electrode 18b, and the activation layer 16a may be formed using one mask (the second mask) in a single etching step, and the FPD may be manufactured using only four masks (first to fourth masks).

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method of manufacturing a thin film transistor (TFT), comprising:
forming a gate electrode on a substrate;
forming a gate insulating layer on the substrate that includes the gate electrode;
forming a semiconductor layer and a metal layer on the gate insulating layer;
forming a photosensitive layer pattern on the metal layer that includes the gate electrode, the photosensitive layer pattern having a center portion having a first thickness and opposing edge portions having a second and larger thickness;
wet etching an exposed portion of the metal layer and a portion of the metal layer under the opposing edge portions of the photosensitive layer pattern using the photosensitive layer to pattern as an etch mask;
removing a uniform thickness of the photosensitive layer pattern while etching an exposed portion of the semiconductor layer by a first etch on the photosensitive layer pattern;
performing a second etch on the photosensitive layer pattern so that the edge portions of the photosensitive layer pattern coincide with side walls of the metal layer; and
dry etching the metal layer and an exposed portion of the semiconductor layer using the photosensitive layer pattern as a mask.

2. The method as claimed in claim 1, wherein the substrate is comprised a material selected from a group consisting of a semiconductor and a transparent insulating material.

3. The method as claimed in claim 1, wherein the semiconductor layer is comprised of a material selected from a group consisting of amorphous silicon and polysilicon.

4. The method as claimed in claim 1, wherein the metal layer is comprised of Mo.

5. The method as claimed in claim 1, wherein the photosensitive layer pattern is produced using a mask selected from a group consisting of a half tone mask and a slit mask.

6. The method as claimed in claim 1, wherein the second etch of the photosensitive layer pattern is a plasma etching process.

7. The method as claimed in claim 1, wherein the dry etching of the metal layer and the semiconductor layer is performed by a plasma etching process, and wherein an SF₆ gas and a chlorine gas are included as reaction gases.

8. A method of manufacturing a flat panel display (FPD), comprising:
forming a gate electrode on a substrate;
forming a gate insulating layer on the substrate that includes the gate electrode;
forming a semiconductor layer and a metal layer on the gate insulating layer;
forming a photosensitive layer pattern on the metal layer that includes the gate electrode, the photosensitive layer pattern having a center portion having a first thickness and opposing edge portions having a second and larger thickness;
wet etching an exposed portion of the metal layer and a portion of the metal layer arranged under the opposing edge portions of the photosensitive layer pattern using the photosensitive layer pattern as an etch mask;
removing a uniform thickness of the photosensitive layer pattern while etching an exposed portion of the semiconductor layer by a first etch on the photosensitive layer pattern;
performing a second etch on the photosensitive layer pattern so that the edge portions of the photosensitive layer pattern coincide with side walls of the metal layer;
forming a source electrode and a drain electrode by etching the metal layer exposed by the photosensitive layer pattern and forming an activation layer by etching exposed portions of the semiconductor layer;
forming a protective layer on the gate insulating layer that includes the source electrode and the drain electrode;
exposing one of the source electrode and the drain electrode by forming a via hole through the protective layer; and
forming a pixel electrode on the protective layer that is electrically connected to the one of the source electrode and the drain electrode through the via hole.

9. The method as claimed in claim 8, wherein the substrate is comprised of a transparent insulating material.

10. The method as claimed in claim 8, wherein the semiconductor layer is comprised of a material selected from a group consisting of amorphous silicon and polysilicon.

11. The method as claimed in claim 8, wherein the metal layer is comprised of Mo.

12. The method as claimed in claim 8, wherein the photosensitive layer pattern is produced by using a mask selected from a group consisting of a half tone mask and a slit mask.

13. The method as claimed in claim 8, wherein the second etch of the photosensitive layer pattern is a plasma etching process.

14. The method as claimed in claim 8, wherein the dry etching of the metal layer and the semiconductor layer is performed by a plasma etching process, and wherein an SF₆ gas and a chlorine gas are included as reaction gases.

15. The method as claimed in claim 8, wherein the pixel electrode is comprised of a transparent conductive material.
